(19) United States
(12) Patent Application Publication
(10) Pub. No.: US 2007/0231751 A1
(43) Pub. Date: Oct. 4, 2007

(54) Photoresist top coat out-of-band illumination filter for photolithography

(76) Inventors: Robert L. Bristol, Portland, OR (US); Makarem A. Hussein, Beaverton, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/395,880

(22) Filed: Mar. 31, 2006

(51) Int. Cl. G03F 7/20

(52) U.S. Cl. 430/322

(57) ABSTRACT

An out-of-band illumination filter for use in photolithography in the form of a top coat on a photoresist is described. The top coat may used by applying a photoresist to a substrate, applying a top coat to the photoresist to prevent out-of-band illumination from exposing the photoresist, and exposing the photoresist in a lithography tool.

### FIELD

The present description relates to photolithography for microelectronic and micromechanical devices and, in particular, to using a protective top coat over a photoresist layer before exposure to reduce the impact of out-of-band illumination on the photoresist.

### BACKGROUND

Lithography is used in the fabrication of semiconductor devices. In lithography, a light sensitive material, called a photoresist, coats a wafer substrate. The photoresist may be exposed to light reflected from a mask to reproduce an image of the mask. When the wafer and mask are illuminated, the photoresist undergoes chemical reactions and is then developed to produce a replicated pattern of the mask on the wafer.

Extreme Ultraviolet (EUV) lithography is a promising future lithography technique. EUV light may be produced from a plasma at sufficient temperature to radiate in the desired wavelength, e.g., in a range of approximately 11 nm to 15 nm. The plasma may be created in a vacuum chamber, typically by driving a pulsed electrical discharge through the target material or by focusing a pulsed laser beam onto the target material. The light produced by the plasma is then collected by nearby mirrors, such as multilayer Si/Mo mirrors, and reflected off the mask.

A problem with EUV plasma sources is that they generate light at many other wavelengths than the desired 13.5 nm. Sources currently proposed produce a large amount of light across a range of 150 to 300 nm (called OOB or out-of-band radiation). There are also other wavelength ranges at which light is produced, but these are currently considered to be less important. Light in the 150-300 nm range will be reflected off the multilayer Si/Mo mirrors and in doing so will expose the photoresist on the wafer. These relatively long wavelengths will not properly focus onto the features of interest, but are still sufficiently energetic to activate the photoresist, thus degrading the overall pattern fidelity.

### BRIEF DESCRIPTION OF THE DRAWINGS

Embodiments of the present invention may be understood more fully from the detailed description given below and from the accompanying drawings of various embodiments of the invention. The drawings, however, should not be taken to be limiting, but are for explanation and understanding only.

FIG. 1 is a diagram of a cross-section of a wafer showing a layer onto which a pattern is to be transferred;

FIG. 2 is a diagram of a cross-section of the wafer of FIG. 1 after the application of an EUV photoresist layer which is used to transfer the pattern from a lithography mask;

FIG. 3A is a diagram of a cross-section of the wafer of FIG. 2 after applying a top coat to the photoresist using a spin-coat process according to an embodiment of the invention;

FIG. 3B is a diagram of a cross-section of the wafer of FIG. 2 showing diagrammatically the application of a top coat to the photoresist via condensation from a vapor phase according to an embodiment of the invention;

FIG. 4A shows the output light wavelength spectrum of an EUV source with EUV radiation and OOB radiation;

FIG. 4B is a diagram of a cross section of the wafer of FIG. 3A or 3B diagramming exposure of the photoresist by EUV light according to an embodiment of the invention;

FIG. 5 is a diagram of a cross section of the wafer of FIG. 4B after exposure to show the impact on the photoresist after EUV exposure in the presence of the top-coat according to an embodiment of the invention;

FIG. 6 is a diagram of a cross-section of the wafer of FIG. 5 after the photoresist and top coat have been developed according to an embodiment of the invention; and

FIG. 7 is a process flow diagram for applying a top coat to photoresist on wafer and developing the photoresist according to an embodiment of the invention.

### DETAILED DESCRIPTION

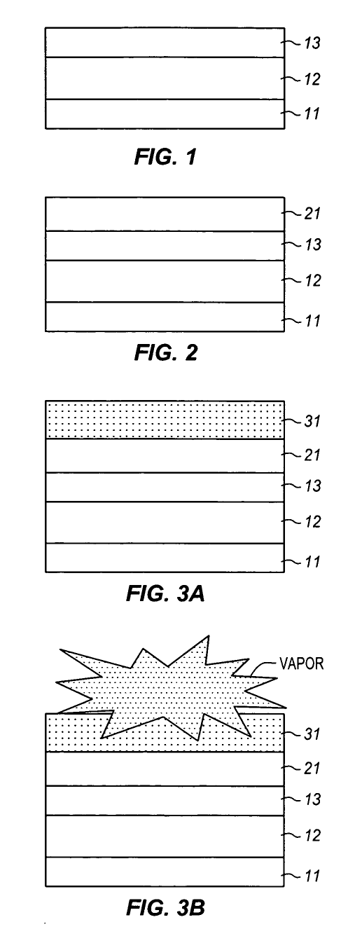

FIG. 1 shows layer 13 to be patterned that is deposited onto a silicon substrate 11 that may have prior structure 12. The top layer 13 may be patterned by printing a pattern onto the top layer 13 using EUV lithography. The pattern may consist of line-space combinations or other combinations of shapes and structures. To print the pattern, an EUV-sensitive photoresist layer 21, shown in FIG. 2 may be applied over the top layer 13 using a spin-coat process or any other typical lithographic process. The photoresist may be further processed in any of a variety of different ways, depending on the photoresist and the process parameters, such as baking, curing, annealing, etc.

The wafer has a substrate 11, typically of silicon, but the choice of substrate will depend upon the particular process that has been selected. Other substrate materials may include gallium arsenide, germanium, lithium niobate and ceramics. Over the substrate some number of layers 12 have been formed to implement a portion of the microelectronic or micromechanical devices that the eventual device is to contain. There may be one or hundreds of layers.

As shown in FIG. 3A, a top-coat DUV (Deep Ultraviolet) filter (TCDF) material 31 is then applied onto the photoresist layer 21. The TCDF material thickness ranges from 20-100 nm. The TCDF may serve as a sacrificial light absorbing layer for the OOB light, or as a reflector. The selected material may degrade in the presence of the OOB illumination or not depending on the choice of material. In one embodiment of the invention, the TCDF material is synthesized by incorporating an inorganic dye that exhibits high absorption characteristics in the DUV wavelength range, such as Si, Ti, Zr, or oxides thereof including ZnO, into a silica-based monomer solution. In another embodiment, the TCDF material is synthesized by incorporating nano-size particles of elements or compounds such as Si, Ti, Zr, or ZnO, into a carrying agent, like HMDS (Hexamethyldisilizane). The carrying agent may be selected to be soluble in the photo-resist developer, such as a water-based or solvent-based carrying agent. In another embodiment, the TCDF material may be formed using Cu, W, Al, or Ti or another conductive or nonconductive material. Since the use of TCDF on a wafer is completely independent of the light source and its optics, it may be used instead of, or, in addition to any filters, or other OOB blocking devices in the optical system.

A TCDF material may be applied onto the EUV photoresist 21 by a spin-coat process, as shown in FIG. 3A, by condensation from a vapor phase, as schematically illustrated in FIG. 3B or in a variety of other ways. When the TCDF is deposited from vapor phase, a high wafer temperature (110 C-200 C) may be required. The TCDF may also be applied in a variety of other ways, depending on the intended use and process parameters. Other ways may include using a dispersion of nanoparticles, or spraying the top coat and a carrier solution as a mist of fine droplets. The application process may be selected to prevent the TCDF 13 from intermixing with the underlying photoresist layer 21. This may enhance the effectiveness of the top coat.

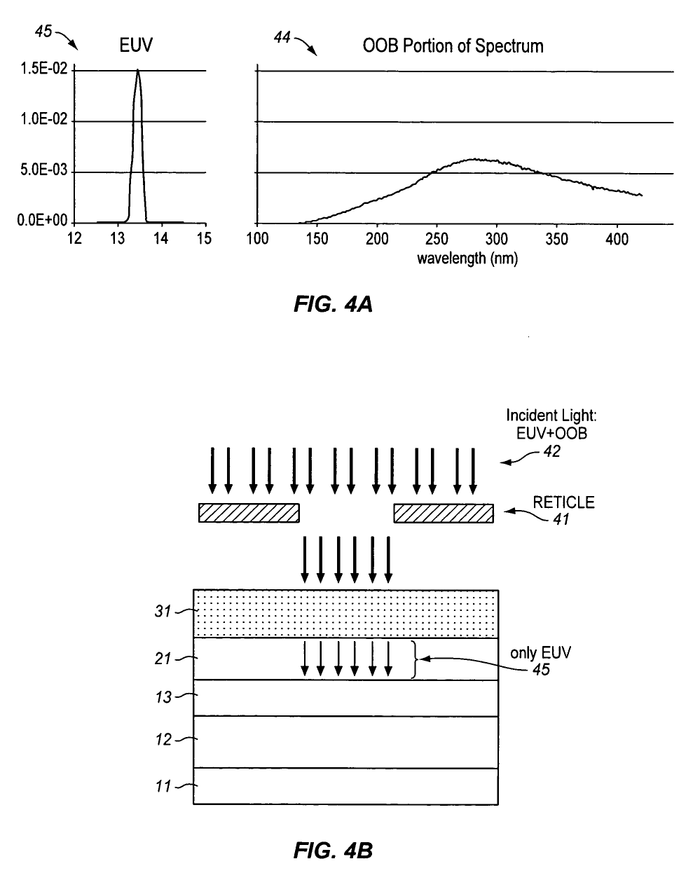

A pattern may be transferred from a reticle or mask 41 onto the layer to be patterned 31 using EUV exposure equipment. As shown in FIG. 4A, the exposure equipment generates a light spectrum characterized by a sharp peak 45 at 13.5 nm, the desired EUV wavelength, and a broader portion 44 that covers the wavelength range from 1100 nm-400 nm. Therefore, the light spectrum radiating and passing through the open areas of the reticle includes the desired 13.5 nm peak and the OOB broader portion of the spectra, as well. It is the function of the TCDF layer to block the OOB portion of the spectrum from reaching the EUV photoresist layer 21.

As shown diagrammatically in FIG. 4B the incident light 42 includes EUV light and OOB light. Both light waveband groups pass through, or are reflected off, the reticle and impinge on the TCDP 31 as shown. The TCDF absorbs the OOB light so that the photoresist 21 is only exposed to the EUV light 45.

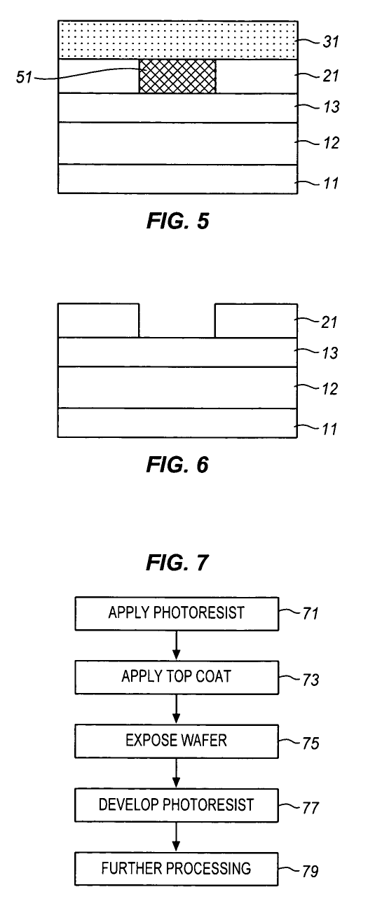

The exposed region of the photoresist 51, as shown in FIG. 5, is cross-linked upon exposure to the EUV light and becomes soluble in the subsequent development step. FIG. 6 shows a diagram of the wafer after development with the exposed region now removed. After development, the photoresist may be baked to complete the image transfer process as is typical for the photo-amplified family of photoresists, of which currently proposed EUV photoresist is a member. However, the particular processes to be applied to deposit, expose, develop and remove the photoresist may be adapted to suit different photoresist materials and different lithography process parameters.

In one embodiment, the TCDF layer may be soluble in the same developer that is used for the exposed photoresist. This allows the exposed region of the photoresist and the TCDF to both be removed during the developing process. For example, the carrier for applying the TCDF may be water soluble or solvent-based. The process sequence outlined by FIGS. 1 through 6 results in a high quality pattern transfer from the reticle or mask 41 into the photoresist EUV photoresist layer using EUV spectrum that is free from OOB light.

FIG. 7 shows an example of how a protective top coat (TCDF) may be used as part of a photolithography process. At block 71, a photoresist layer is applied to the substrate. This may be done in any of a variety of conventional ways, as described above. At block 73, a top coat filter layer is applied over the photoresist, such as an inorganic dye, an oxide, or a metal in any of the ways described above. If a condensation process is used, it may be similar to that used in depositing HMDS (Hexamethyldisilizane) before a photoresist layer is applied. The carrier material may then be removed before the photoresist is exposed. With this alternative, the thickness of the top coat layer need not be so precisely controlled.

After the top coat is applied, the wafer is exposed at block 75. The intended illumination wavelengths, such as EUV light, expose the photoresist, passing at least partially through the top coat. Out-of-band illumination, such as DUV light is at least partially absorbed or reflected by the top coat. As a result, the photoresist is exposed more effectively with the intended pattern. The photoresist is then developed and the top coat is removed at block 77 to create the intended photoresist patterning. The wafer then proceeds with the rest of the chipmaking process. Other layers are applied at block 79 between or over the photoresist to create the various structures that are intended for the wafer. While with some materials the top coat will be mostly or completely removed when the photoresist is developed. For some materials, it may be necessary to add another step to remove the top coat after exposure either before or while the photoresist is developed.

It is to be appreciated that a lesser or more complex top coat layer, wafer configuration, photoresist development and removal and photolithography process or system may be used than those shown and described herein. Therefore, the configurations may vary from implementation to implementation depending upon numerous factors, such as price constraints, performance requirements, technological improvements, or other circumstances. Embodiments of the invention may also be applied to other types of photolithography systems that use different materials and devices than those shown and described herein.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In other instances, well-known circuits, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. A method comprising:
applying a photoresist to a substrate;
applying a top coat to the photoresist to prevent out-of-band illumination from exposing the photoresist; and
exposing the photoresist in a lithography tool.

2. The method of claim 1, further comprising removing the topcoat.

3. The method of claim 1, further comprising developing the photoresist and simultaneously removing the top coat.

4. The method of claim 1, wherein the top coat is removed with a water-based photoresist developer solution.

5. The method of claim 1, wherein the top coat is removed with a solvent-based photoresist developer solution.

6. The method of claim 1, wherein applying the top coat comprises spin-coating the top coat over the photoresist.

7. The method of claim 1, wherein applying the top coat comprises condensing the top coat as a dispersion of nanoparticles over the photoresist from a vapor phase.

8. The method of claim 1, wherein the top coat includes inorganic dye.

9. The method of claim 1, wherein the top coat comprises a sacrificial light absorbing layer.

10. The method of claim 1, wherein the top coat comprises at least one of Si, Ti, Zr, and Zn, or oxides thereof.

11. The method of claim 1, wherein the top coat comprises a conductive metal layer.

12. The method of claim 1, wherein the top coat comprises at least one of Cu, W, Al, and Ti.

13. The method of claim 1, wherein the top coat does not intermix with the photoresist.

14. A microelectronic device comprising structures formed by lithography, the lithography being performed at least in part by:
applying a photoresist to a substrate;
applying a top coat to the photoresist to prevent out-of-band illumination from exposing the photoresist; and
exposing the photoresist in a lithography tool.

15. The device of claim 14, wherein the top coat includes inorganic dye.

16. The device of claim 14, wherein the top coat comprises at least one of Si, Ti, Zr, and Zn, or oxides thereof.

17. The device of claim 14, wherein the lithography is further performed by developing the photoresist and simultaneously removing the top coat.

18. A composition for use as a top coat over a photoresist in photolithography, the composition comprising:
an inorganic dye that obstructs out-of-band illumination and is transparent to an intended band of illumination; and
a carrying agent that dissolves in a developer of the photoresist,
wherein the composition does not intermix with the photoresist.

19. The composition of claim 18, wherein the inorganic dye comprises at least one of Si, Ti, Zr, and Zn, or oxides thereof.

20. The composition of claim 18, wherein the carrying agent comprises hexamethyldisilizane.
